(19) United States
(12) Patent Application Publication
(10) Pub. No.: US 2019/0326923 A1
(43) Pub. Date: Oct. 24, 2019

(54) Multi-Ladder Digital to Analog Converter

(71) Applicant: Maxlinear, Inc., Carlsbad, CA (US)

(72) Inventors: Baradwaj Vigraham, Carlsbad, CA (US); Rakesh Kumar Palani, Irvine, CA (US); Suman Sah, Colorado Springs, CO (US)

(21) Appl. No.: 16/389,808

(22) Filed: Apr. 19, 2019

Related U.S. Application Data
(60) Provisional application No. 62/660,274, filed on Apr. 20, 2018.

(51) Int. Cl. H03M 1/78

(52) U.S. Cl. CPC H03M 1/785

(57) ABSTRACT

A system (e.g., a transmitter system on chip) comprises a digital-to-analog converter configured to convert an N-bit digital signal to a corresponding analog signal, where N is an integer greater than 1. The digital-to-analog converter may comprise N bias circuits, where each of the bias circuits is configured to generate a bias current, and route the bias current based on a value of a respective one of the N bits of the N-bit digital signal. Each of the N bias circuits may comprises a resistor network and a pair of switching circuits.

### PRIORITY CLAIM

This application claims priority to U.S. provisional application 62/660,274 titled “Multi-Ladder Digital to Analog Converter” and filed Apr. 20, 2018, which is hereby incorporated herein by reference.

### BACKGROUND

Limitations and disadvantages of conventional approaches to digital-to-analog converters will become apparent to one of skill in the art, through comparison of such systems with some aspects of the present invention as set forth in the remainder of the present application with reference to the drawings.

### BRIEF SUMMARY OF THE INVENTION

A system and/or method is provided for a multi-ladder digital-to-analog converter, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 shows an example implementation of a 3-bit multi-ladder digital-to-analog converter (DAC).

FIG. 2 shows a block diagram comprising the multi-ladder DAC of FIG. 1.

FIG. 3 illustrates operation of the DAC of FIG. 1.

FIG. 4 shows another example implementation of a multi-ladder DAC of FIG. 1.

FIG. 5 shows another example implementation of a multi-ladder DAC of FIG. 1.

### DETAILED DESCRIPTION OF THE INVENTION

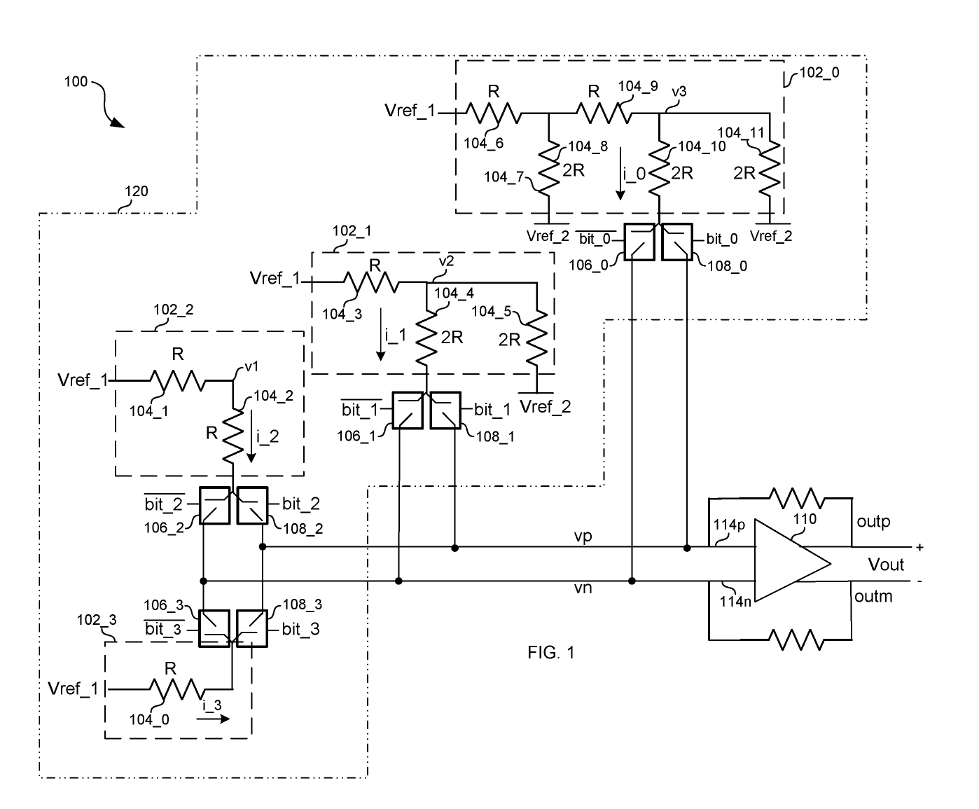

FIG. 1 shows an example implementation of a 4-bit multi-ladder digital-to-analog converter (DAC). Aspects of this disclosure are applicable to any N-bit DAC, where N is an integer. For simplicity of illustration, N was chosen to be four in FIG. 1. The N-bit DAC 100 comprises N bias circuits 102, 2N switching circuits 106 and 108, and an operational amplifier 110.

The DAC 100 converts the 4-bit digital value bit_0, bit_1, bit_2, bit_3 (bit_0 being the least-significant bit and bit_3 being the most-significant bit) to a corresponding analog voltage Vout (the voltage between outp and outn).

Each of the 2N switching circuits is open or closed based on the state of its input. That is, if bit_n is ‘1’, then 106_n is open and 108_n is closed. Conversely, if bit_n is ‘0’, then 106_n is closed and 108_n is open.

In the example implementation shown, the bias circuit 102_3 comprises a single resistor 104 coupled between a first reference voltage, Vref_1 (e.g., 1 volt DC) and the switching circuits 106_3 and 108_3. The second bias circuit 102_2 comprises two resistors 104 coupled between the first reference voltage and the switching circuits 106_2 and 108_2. Each of the bias circuits 102_1 and 102_0 comprises a plurality of resistors 104 coupled between Vref_1, a second reference voltage, Vref_2 (e.g., 0 volts DC), and a respective pair of switching circuits 106 and 108. Resistors 104 labeled with ‘R’ are unit resistance (e.g., 1 kΩ)) and resistors 104 labeled ‘2R’ are twice the unit resistance (e.g., 2 kΩ)). The resistors of each bias circuit 102_n (n being an integer between 0 and N) are arranged to generate a desired current, i_n, through the closed one of the switches 106_n and 108_n. In the example shown, the desired currents are binary-weighted such that, for the example 4-bit DAC (i.e., N=4), and assuming Vref_2=0:i_0=Vref_1/8R, i_1=Vref_1/4R, and i_2=Vref_1/2R, and i_1=Vref/R. Thus, in the example shown, each successive bias circuit n+1 provides a current that is higher by an additional factor of 2. Implementations configured to convert higher numbers of bits may include additional bias circuits comprising multiple resistors of unit resistance R. For example, a 5-bit converter may additionally comprise a bias circuit 102_4 comprising two unit-resistance resistors 104 in parallel between Vref and switching circuit 106_4 and 108_4 controlled by bit_4, a 6-bit converter may additionally comprise four unit-resistance resistors in parallel between Vref_1 and switches 106_5 and 108_5 controlled by bit_5, and so on.

By using a separate bias circuit 102 for each bit of the DAC 100, each current i_n is independent (to a determined precision) of the value of the other bits of the DAC 100. For example, current i_0 is independent of the values of bits_1, bit_2, and bit_3. Conversely, if a single bias network was used to generate the currents i_0, i_1, i_2, and i_3, there would be much more variation in i_0 depending on the values of bit_1, bit_2, and bit_3 because the virtual ground at the input of operation amplifier 110 can never be perfectly ideal (instead of both inputs being exactly 0 V, one has a voltage vp and the other has a voltage vn).

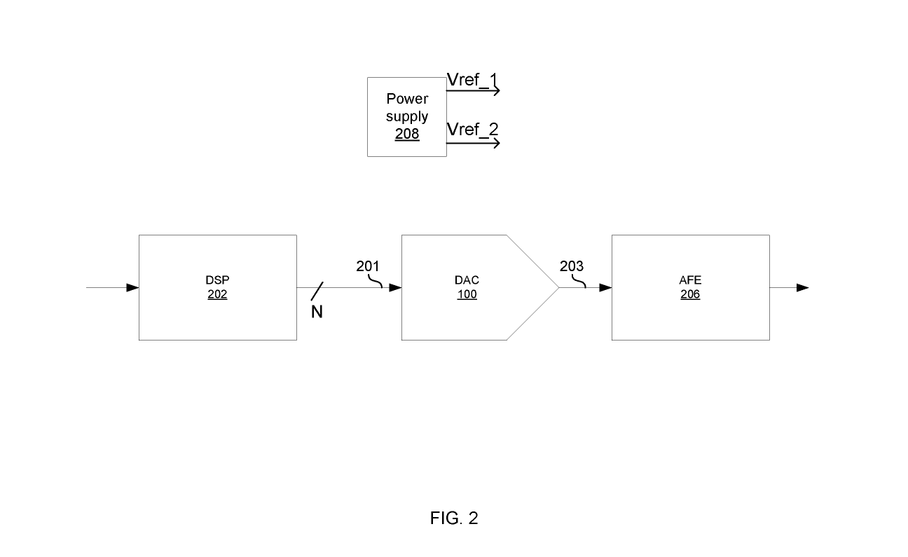

FIG. 2 shows a block diagram of a transmitter comprising the multi-ladder DAC of FIG. 1. The example transmitter comprises digital signal processing (DSP) circuitry 202, DAC 100, analog front-end (AFE) circuitry 206, and power supply circuitry 208.

The DSP circuitry 202 is operable to generate a digital signal to be transmitted onto a communication medium. The DSP 202 may, for example, perform forward error correction encoding, bit-to-symbol mapping, filtering, and/or other operations.

The DAC 100 is as described above with reference to FIG. 1 and is operable to convert the digital signal 201 output by DSP circuitry 202 to corresponding analog signal 203.

The AFE circuitry 206 is operable to condition the analog signal 203 for output onto the communication medium. The AFE circuitry 206 may, for example, filter and amplify the signal 203.

The power supply circuitry 208 comprises circuitry operable to generate one or more reference voltages and/or currents. In an example implementation it generates a first direct current reference voltage Vref_1 and a second direct current reference voltage Vref_2.

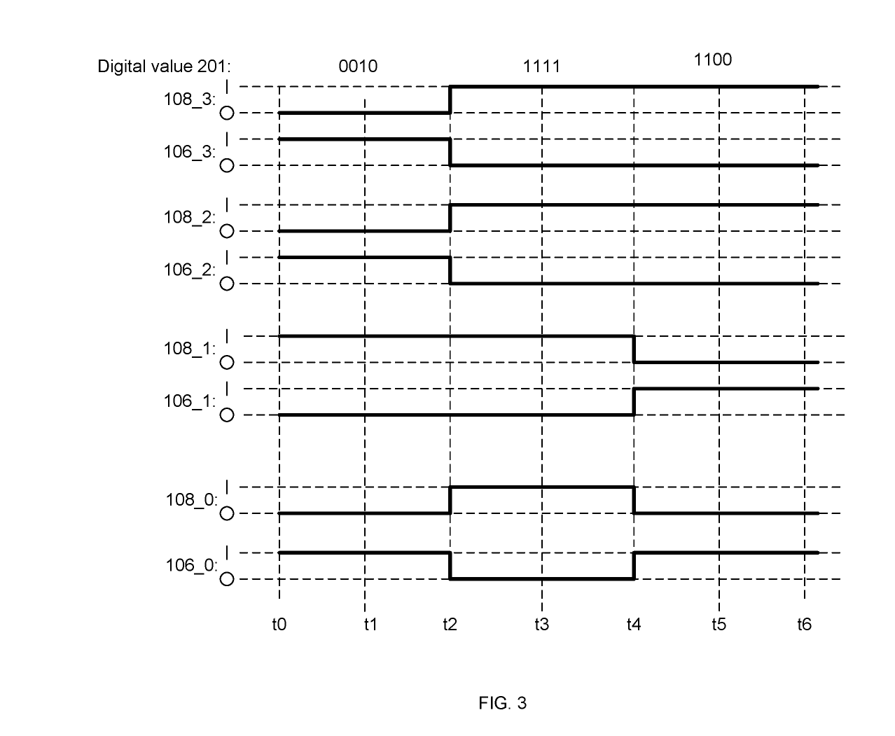

FIG. 3 illustrates operation of the DAC of FIG. 1. FIG. 3 shows an example digital signal to be converted to analog and corresponding control of the switching circuits 106_0-106_3 and 108_0-108_3.

At time t0 the digital value to be converted to analog is set to 0010. Thus, switching circuits 106_0, 108_1, 106_2, and 106_3 are closed and switching circuits 108_0, 106_1, 108_2, and 108_3 are opened. Then at t1 (after some settling time), i_0, i_2, and i_3 flow to the negative input 114n of the op amp 110 and i_1 flows to the positive input 114p of op amp 110.

At time t2 the digital value to be converted to analog is set to 1111. Thus, switching circuits 108_0, 108_1, 108_2, and 108_3 are closed and switching circuits 106_0, 106_1, 106_2, and 106_3 are opened. Then at t3 (after some settling time), i_0, i_1, i_2, and i_3 flow to the positive input 114n of the op amp 110.

At time t4 the digital value to be converted to analog is set to 1100. Thus, switching circuits 106_0, 106_1, 108_2, and 108_3 are closed and switching circuits 108_0, 108_1, 106_2, and 106_3 are opened. Then at t5 (after some settling time), i_2 flows to the positive input 114n of the op amp 110 and i_0 and i_1 flow to the negative input 114p of op amp 110.

In accordance with an example implementation of this disclosure a system (e.g., a transmitter system on silicon chip) comprises a digital-to-analog converter (e.g., 100) configured to convert an N-bit digital signal (e.g., 201) to a corresponding analog signal (e.g., 203), where N is an integer greater than 1. The digital-to-analog converter may comprise N bias circuits (e.g., 102_0-102_3), where each of the bias circuits is configured to generate a bias current (e.g., one of i_0, i_1, i_2, and i_2), and route the bias current based on a value of a respective one of the N bits of the N-bit digital signal (e.g., route i_0 based on bit_0 of signal 201, i_1 based on bit_1 of signal 201, and so on). Each of the N bias circuits may comprise a resistor network (e.g., 104_1 and 104_2 or 104_6-104_10) and a pair of switching circuits (e.g., 106_0 and 108_0 or 106_2 and 108_2). The pair of switching circuits may comprise a first switching circuit (e.g., 106_0) that is open when a first bit of the N-bit digital signal is a first logic value (e.g., 1 or “high”) and closed when the first bit of the N-bit digital signal is a second logic value (e.g., 0 or “low”), and a second switching circuit (e.g., 108_0) that is open when the first bit of the N-bit digital signal is the second logic value and closed when the first bit of the N-bit digital signal is the first logic value. A first bias circuit (e.g., 102_2) of the N bias circuits comprises a resistive voltage divider (e.g., 104_1 and 104_2) coupled (e.g., via conductive trace) between a first reference voltage (e.g., vref_1) and a first pair of switching circuits (e.g., 106_2 and 108_2). The first pair of switching circuits may be controlled by a first bit (e.g., bit_2) of the N-bit digital signal. A second bias circuit of the N bias circuits may comprise a resistor network (e.g., 104_3-104_5) electrically coupled (e.g., via conductive traces) to the first reference voltage (e.g., Vref_1), a second reference voltage (e.g., Vref_2), and a second pair of switching circuits (e.g., 106_1 and 108_1). The second pair of switching circuits may be controlled by a second bit (e.g., bit_1) of the N-bit digital signal. The N bias circuits may comprise N resistor networks (e.g., 104_0, 104_1-104_2, 104_3-104_5, and 104_6-104_10). Each of the N resistor networks is conductively coupled to each other of the N resistor networks only, if at all, through one or more traces (e.g., metal and/or polysilicon) carrying a respective one or more reference voltages. That is, the N resistor networks may be electrically isolated from each other except for being connected to the reference voltages Vref_1 and Vref_2. The N bias circuits may comprise N resistor networks, and no trace other than one or more traces carrying a respective one or more reference voltages (e.g., one trace/bus carrying Vref_1 and one trace carrying Vref_2) is coupled to more than one of the N resistor networks.

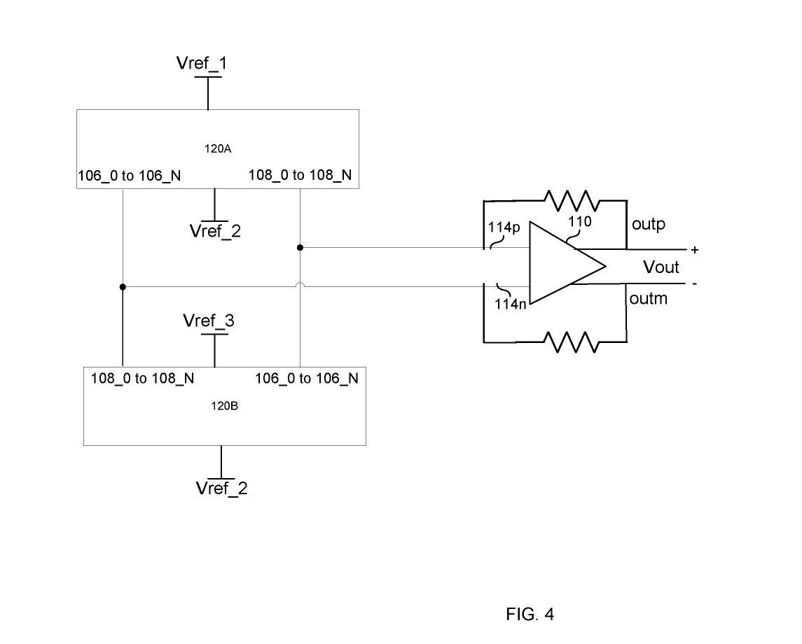

FIG. 4 shows another example implementation of a multi-ladder DAC of FIG. 1. In FIG. 4, the DAC comprises two instances of the ladder network 120 (called out as 120A and 120B). The first ladder network 120A is between Vref_1 and Vref_2, has its switches 106_0 to 106_N coupled to Vn, and has its switches 108_0 to 108_N coupled to Vp. The second ladder network 120A is between Vref_3 (which may be a voltage equal to Vref_1 but electrically isolated from Vref_1) and Vref_4 (which may be a voltage equal to Vref_2 but electrically isolated from Vref_2), has its switches 108_0 to 108_N coupled to Vn, and has its switches 106_0 to 106_N coupled to Vp. The additional ladder network 120B coupled to different voltage rails and different polarity of switches 108 and 108 results in constant (to a determined precision) impedance seen looking back from the inputs of the amplifier 110.

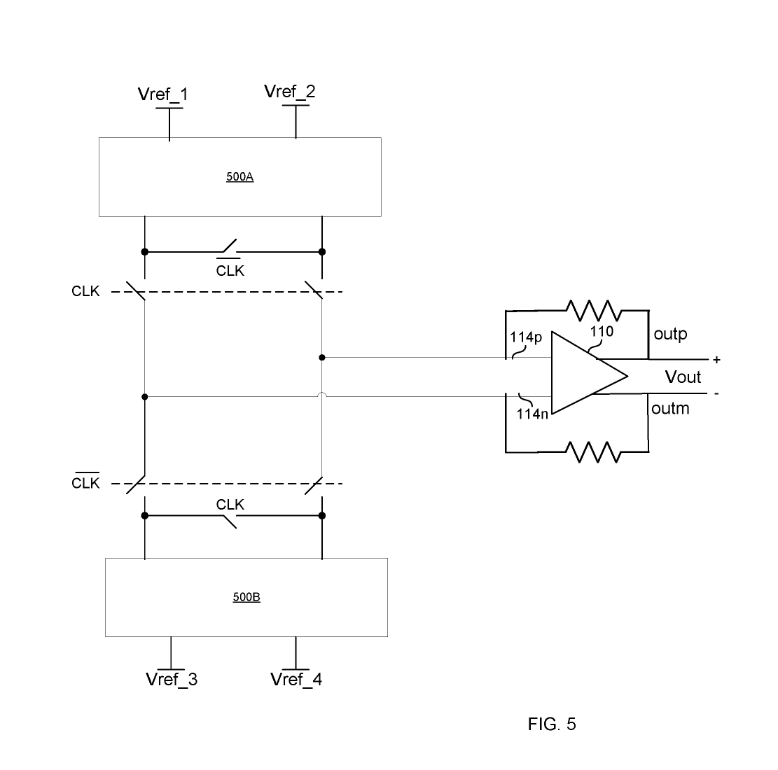

FIG. 5 shows another example implementation of a multi-ladder DAC of FIG. 1. In FIG. 5, the DAC comprises two circuits 500A and 500B each of which may be a ladder network 120, or may be a pair of ladder networks 120A and 120B as shown in FIG. 4. When CLK is high, the circuit 500A is connected to Vp and Vn and the inputs of circuit 500B are shorted together. When CLK is low, the circuit 500B is connected to Vp and Vn and the inputs of circuit 500A are shorted together.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the processes as described herein.

Accordingly, the present invention may be realized in hardware, software, or a combination of hardware and software. The present invention may be realized in a centralized fashion in at least one computing system, or in a distributed fashion where different elements are spread across several interconnected computing systems. Any kind of computing system or other apparatus adapted for carrying out the methods described herein is suited. A typical combination of hardware and software may be a general-purpose computing system with a program or other code that, when being loaded and executed, controls the computing system such that it carries out the methods described herein. Another typical implementation may comprise an application specific integrated circuit or chip.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A system comprising:
a digital-to-analog converter configured to convert an N-bit digital signal to a corresponding analog signal, wherein:
N is an integer greater than 1;
the digital-to-analog converter comprises N bias circuits; and
each of the bias circuits is configured to:
generate a bias current; and
route the bias current based on a value of a respective bit of the N-bit digital signal.

2. The system of claim 1, wherein each of the N bias circuits comprises a resistor network and a pair of switching circuits.

3. The system of claim 2, wherein the pair of switching circuits comprises:
a first switching circuit that is open when a first bit of the N-bit digital signal is a first logic value and closed when the first bit of the N-bit digital signal is a second logic value; and
a second switching circuit that is open when the first bit of the N-bit digital signal is the second logic value and closed when the first bit of the N-bit digital signal is the first logic value.

4. The system of claim 1, wherein a first bias circuit of the N bias circuits comprises a resistor voltage divider coupled between a first reference voltage and a first pair of switching circuits.

5. The system of claim 4, wherein the first pair of switching circuits are controlled by a first bit of the N-bit digital signal.

6. The system of claim 4, wherein a second bias circuit of the N bias circuits comprises a resistor network coupled to the first reference voltage, a second reference voltage, and a second pair of switching circuits.

7. The system of claim 6, wherein the second pair of switching circuits are controlled by a second bit of the N-bit digital signal.

8. The system of claim 1, wherein:
the N bias circuits comprises N resistor networks; and
each of the N resistor networks is conductively coupled to each other of the N resistor networks only, if at all, through one or more traces carrying a respective one or more reference voltages.

9. The system of claim 1, wherein:
the N bias circuits comprises N resistor networks; and
no trace other than one or more traces carrying a respective one or more direct current reference voltages is coupled to more than one of the N resistor networks.

10. A system comprising:
a digital-to-analog converter configured to convert an N-bit digital signal to a corresponding analog signal, wherein:
N is an integer greater than 1;
the digital-to-analog converter comprises N bias circuits, each of which generates a respective one of a plurality of bias currents which are selectively coupled to either a positive input of an operational amplifier or a negative input of an operational amplifier; and
each of the N bias circuits is conductively coupled to each other of the N bias circuits only, if at all, through one or more traces carrying one or more reference voltages.

11. The system of claim 10, wherein each of the N bias circuits comprises a resistor network and a pair of switching circuits.

12. The system of claim 11, wherein the pair of switching circuits comprises:
a first switching circuit that is open when a first bit of the N-bit digital signal is a first logic value and closed when the first bit of the N-bit digital signal is a second logic value; and
a second switching circuit that is open when the first bit of the N-bit digital signal is the second logic value and closed when the first bit of the N-bit digital signal is the first logic value.

13. The system of claim 10, wherein a first bias circuit of the N bias circuits comprises a resistive voltage divider coupled between a first of the one or more reference voltages and a first pair of switching circuits.

14. The system of claim 13, wherein the first pair of switching circuits are controlled by a first bit of the N-bit digital signal.

15. The system of claim 13, wherein a second bias circuit of the N bias circuits comprises a resistor network coupled to the first of the one or more reference voltages, a second of the one or more reference voltages, and a second pair of switching circuits.

16. The system of claim 15, wherein the second pair of switching circuits are controlled by a second bit of the N-bit digital signal.

17. The system of claim 10, wherein each of the N bias circuits is configured to:
generate a bias current; and
route the bias current based on a value of a respective bit of the N-bit digital signal.

18. The system of claim 17, wherein the bias current is routed to either a first input of a second input of an operational amplifier.
